(19) United States
(12) Patent Application Publication
(10) Pub. No.: US 2026/0262530 A1
(43) Pub. Date: Sep. 3, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Rie ARIMA, Nomi Ishikawa (JP); Shinya OZAWA, Kanazawa Ishikawa (JP); Masatoshi ARAI, Hakusan Ishikawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/369,614

(22) Filed: Oct. 27, 2025

(30) Foreign Application Priority Data
Mar. 3, 2025 (JP) 2025-032670

(51) Int. Cl. H01L 23/00

(52) U.S. Cl. CPC H10W 72/60; H10W 72/646; H10W 90/766

(57) ABSTRACT

A semiconductor device has a semiconductor chip, a first conductive member, a second conductive member located on a first side with respect to the semiconductor chip, and a connection member disposed to sandwich the semiconductor chip between the connection member and the first conductive member. The semiconductor chip has a first electrode, a second electrode having a plurality of electrode portions, and a partition wall that separates two electrode portions from each other. A surface of the connection member that faces the side on which the semiconductor chip is located has a first portion and a second portion. The second portion is electrically connected to the plurality of electrode portions by a bonding material. The first portion is arranged on the first side of the second portion. The first portion has a lower wettability with respect to the bonding material than that of the second portion.

### CROSS-REFERENCE TO RELATED APPLICATION

This application is based upon and claims the benefit of priority from Japanese Patent Application No. 2025-032670, filed on Mar. 3, 2025; the entire contents of which are incorporated herein by reference.

### FIELD

Embodiments described herein relate generally to a semiconductor device.

### BACKGROUND

Semiconductor devices are known in which connection members are bonded to electrodes of a semiconductor chip by a bonding material such as solder. In such a semiconductor device, the electrodes of the semiconductor chip and the connection members are bonded by melting a bonding material between the electrodes of the semiconductor chip and the connection members. At this time, when the connection member is disposed to be inclined with respect to the semiconductor chip, the molten bonding material may move unevenly to a location at which there is a large gap between the semiconductor chip and the connection member, for example. Here, a portion of the electrode of the semiconductor chip that is exposed on a surface of the semiconductor chip may be divided into a plurality of electrode portions by a partition wall. The partition wall has a lower wettability with respect to the bonding material than that with respect to the plurality of electrode portions. As a result, for example, even when the molten bonding material that has moved unevenly attempts to spread to locations at which the gap between the semiconductor chip and the connection member is small, movement thereof is hindered by the partition wall, and there is a risk that the bonding material will not spread evenly on the electrodes of the semiconductor chip. Thus, there is a risk of problems occurring, such as an increase in on-resistance and thermal resistance of the semiconductor device.

### BRIEF DESCRIPTION OF THE DRAWINGS

FIG. 1 is a cross-sectional view showing a part of a semiconductor device according to a first embodiment and is a cross-sectional view taken along line I-I in FIG. 2.

FIG. 2 is a top view of a part of the semiconductor device according to the first embodiment.

FIG. 3 is a cross-sectional view showing a part of a semiconductor device according to a second embodiment and is a cross-sectional view taken along line III-III in FIG. 4.

FIG. 4 is a top view of a part of the semiconductor device according to the second embodiment.

FIG. 5 is a top view of a part of a semiconductor device according to a first modified example of the second embodiment.

FIG. 6 is a top view of a part of a semiconductor device according to a second modified example of the second embodiment.

FIG. 7 is a cross-sectional view showing a part of a semiconductor device according to a third embodiment and is a cross-sectional view taken along line VII-VII in FIG. 8.

FIG. 8 is a top view of a part of the semiconductor device according to the third embodiment.

FIG. 9 is a cross-sectional view of a part of a semiconductor device according to a fourth embodiment.

FIG. 10 is a cross-sectional view showing a part of a semiconductor device according to a modified example of the fourth embodiment.

FIG. 11 is a cross-sectional view showing a part of a semiconductor device according to a fifth embodiment.

FIG. 12 is a cross-sectional view showing a part of a semiconductor device according to a modified example of the fifth embodiment.

FIG. 13 is a cross-sectional view showing a part of a semiconductor device according to a sixth embodiment.

FIG. 14 is a cross-sectional view showing a part of a semiconductor device in a first modified example of the sixth embodiment.

FIG. 15 is a cross-sectional view showing a part of a semiconductor device in a second modified example of the sixth embodiment.

FIG. 16 is a cross-sectional view showing a part of a semiconductor device in a third modified example of the sixth embodiment.

FIG. 17 is a cross-sectional view showing a part of a semiconductor device according to a seventh embodiment.

FIG. 18 is a cross-sectional view showing a part of a semiconductor device according to a modified example of the seventh embodiment.

FIG. 19 is a cross-sectional view showing a part of a semiconductor device according to a comparative example.

### DETAILED DESCRIPTION

A semiconductor device according to an embodiment includes a semiconductor chip, a first conductive member electrically connected to the semiconductor chip, a second conductive member located on a first side with respect to the semiconductor chip in a predetermined direction perpendicular to a thickness direction of the semiconductor chip, and a connection member disposed to sandwich the semiconductor chip between the first conductive member and the connection member in the thickness direction and configured to electrically connect the semiconductor chip and the second conductive member. The semiconductor chip includes a first electrode configured to form at least a part of a first surface of the semiconductor chip on the side on which the first conductive member is located in the thickness direction, a second electrode having a plurality of electrode portions, and a partition wall having a surface that forms a part of a second surface of the semiconductor chip on the side on which the connection member is located in the thickness direction. Each of the plurality of electrode portions has a surface that forms a part of the second surface. The partition wall separates two of the plurality of electrode portions from each other on the second surface in the predetermined direction. A surface of the connection member which faces the side on which the semiconductor chip is located in the thickness direction has a first portion and a second portion. The second portion overlaps the semiconductor chip when seen in the thickness direction and is electrically bonded to the plurality of electrode portions by a bonding material. The first portion is arranged on the first side of the second portion. A wettability of a portion of the partition wall that forms the second surface with respect to the bonding material is lower than that of the portions of the plurality of electrode portions that form the second surface with respect to the bonding material. The wettability of the first portion with respect to the bonding material is lower than the wettability of the second portion with respect to the bonding material.

Hereinafter, a semiconductor device according to an embodiment will be described with reference to the drawings.

In the drawings, appropriately, the thickness direction of the semiconductor chip of the embodiment is indicated as a Z-axis direction, a direction perpendicular to the thickness direction of the semiconductor chip is indicated as an X-axis direction, and a direction perpendicular to both the Z-axis direction and the X-axis direction is indicated as a Y-axis direction. In the following description, the X-axis direction is referred to as a “first direction X,” the Y-axis direction is referred to as a “second direction Y,” and the Z-axis direction is referred to as a “thickness direction Z.” In addition, the side (the +Z side) in the thickness direction Z to which a Z-axis arrow points is referred to as the “upper side,” and the side (the −Z side) opposite to the side in the thickness direction Z to which the Z-axis arrow points is referred to as the “lower side.” In addition, the side in the X-axis direction to which an arrow in the first direction X points (the +X side) is referred to as the “front side,” and the side (the −X side) opposite to the side in the X-axis direction to which the arrow in the first direction X points is referred to as the “rear side.” In the following embodiments, the first direction X corresponds to a “predetermined direction” perpendicular to the thickness direction Z. The front side corresponds to a “first side in the predetermined direction.” The rear side corresponds to a “second side in the predetermined direction.” The terms “upper side,” “lower side,” “front side,” and “rear side” are simply names used to describe the relative positional relationships of each part, and the actual arrangement relationships, or the like may be arrangement relationships other than the arrangement relationships, or the like indicated by these names.

### First Embodiment

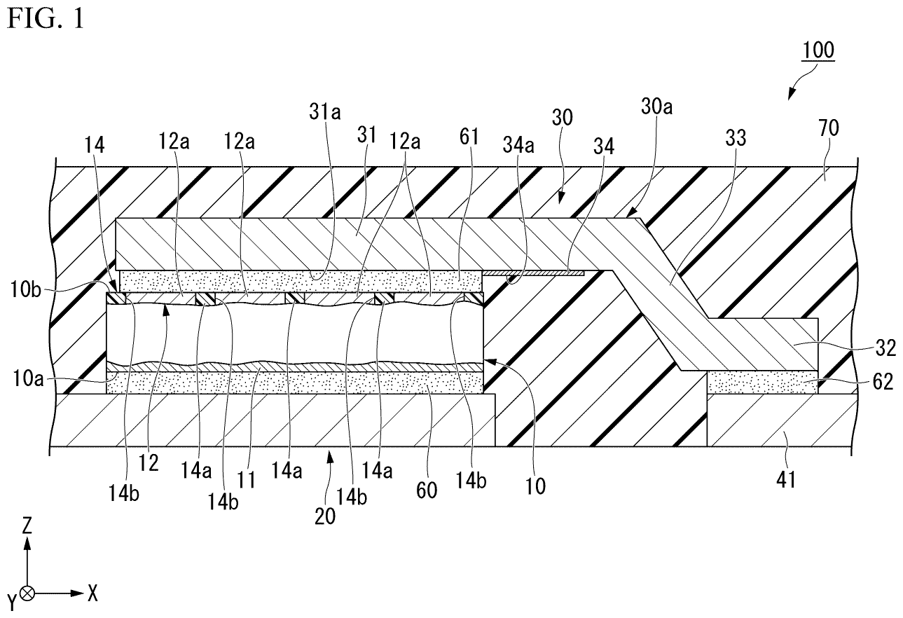

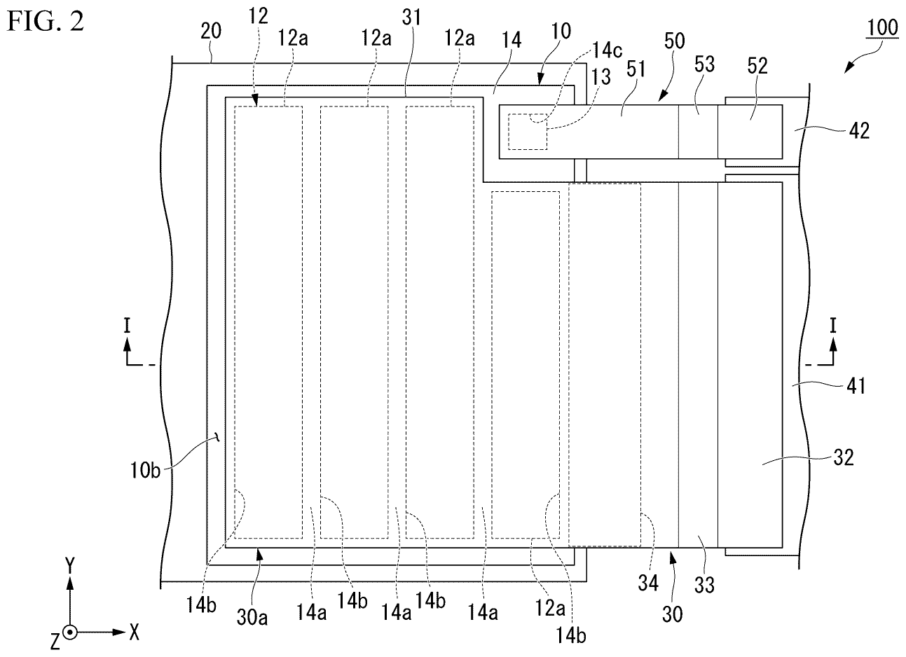

FIG. 1 is a cross-sectional view showing a part of a semiconductor device 100 according to a first embodiment and is a cross-sectional view taken along line I-I in FIG. 2. FIG. 2 is a top view of a part of the semiconductor device 100 according to the first embodiment. Only a part of a semiconductor chip 10 is shown in cross section in FIG. 1. In FIG. 2, a resin portion 70 is omitted.

As shown in FIG. 1, the semiconductor device 100 includes the semiconductor chip 10, a first conductive member 20, a first connection member 30, a second conductive member 41, and the resin portion 70. As shown in FIG. 2, the semiconductor device 100 includes a second connection member 50 and a third conductive member 42.

The semiconductor chip 10 is a transistor having a vertical structure. In the first embodiment, the semiconductor chip 10 is a field effect transistor (FET). The semiconductor chip 10 is, for example, a metal-oxide-semiconductor field-effect transistor (MOSFET). As shown in FIGS. 1 and 2, the semiconductor chip 10 is a plate-like chip of which a dimension in the thickness direction Z is smaller than dimensions in the first direction X and the second direction Y. The semiconductor chip 10 is sandwiched in the thickness direction Z between the first conductive member 20 and the first connection member 30.

As shown in FIG. 1, the semiconductor chip 10 has a first electrode 11. The first electrode 11 forms at least a part of a surface of the semiconductor chip 10 on the side (the −Z side) on which the first conductive member 20 is located in the thickness direction Z, that is, a lower surface 10a. The lower surface 10a is a surface of the semiconductor chip 10 on the lower side. The lower surface 10a faces downward. In the first embodiment, the lower surface 10a corresponds to a “first surface.” In the first embodiment, the entire lower surface 10a of the semiconductor chip 10 is formed by a surface of the first electrode 11 on the lower side. In the first embodiment, the first electrode 11 is a drain electrode. The first electrode 11 is electrically bonded to the first conductive member 20 by a bonding material 60. The bonding material 60 has electrical conductivity. The bonding material 60 is a material that may electrically bond objects together by attaching the objects to each other in a molten state and then being hardened. In the first embodiment, the bonding material 60 is solder.

The semiconductor chip 10 has a second electrode 12. In the first embodiment, the second electrode 12 is a source electrode. The second electrode 12 has a plurality of electrode portions (electrodes) 12a. Each of the plurality of electrode portions 12a has a surface of the semiconductor chip 10 on the side (the +Z side) on which the first connection member 30 is located in the thickness direction Z, that is, a surface that forms a part of an upper surface 10b. In the first embodiment, the upper surfaces of the plurality of electrode portions 12a form a part of the upper surface 10b. The upper surface 10b is an upper surface of the semiconductor chip 10. The upper surface 10b faces upward. In the first embodiment, the upper surface 10b corresponds to a “second surface.” In the first embodiment, a part of the upper surface 10b of the semiconductor chip 10 is formed by the upper surfaces of the plurality of electrode portions 12a.

As shown in FIG. 2, in the first embodiment, the plurality of electrode portions 12a are arranged at intervals in the first direction X. The plurality of electrode portions 12a extend in the second direction Y. In the first embodiment, the plurality of electrode portions 12a have a rectangular shape that is long in the second direction Y when seen in the thickness direction Z. There is no particular limitation on a shape of the plurality of electrode portions 12a when seen in the thickness direction Z. In the first embodiment, the number of the plurality of electrode portions 12a is four. The number of electrode portions 12a is not particularly limited as long as it is two or more.

The semiconductor chip 10 has a third electrode 13. In the first embodiment, the third electrode 13 is a gate electrode. The third electrode 13 has a surface that forms a part of the upper surface 10b of the semiconductor chip 10. An upper surface of the third electrode 13 forms a part of the upper surface 10b.

The semiconductor chip 10 has an insulation portion 14. The insulation portion 14 has insulating properties. The insulation portion 14 is made of, for example, a resin. The insulation portion 14 is an insulating layer formed of, for example, polyimide. The insulation portion 14 has a surface that forms a part of the upper surface 10b. In the first embodiment, an upper surface of the insulation portion 14 forms a part of the upper surface 10b. In the first embodiment, the upper surface 10b of the semiconductor chip 10 is formed by the upper surfaces of the plurality of electrode portions 12a, the upper surface of the third electrode 13, and the upper surface of the insulation portion 14.

A plurality of first openings 14b that open upward are formed in the insulation portion 14. The plurality of first openings 14b are arranged in the first direction X at intervals. The plurality of first openings 14b extend in the second direction Y. In the first embodiment, each of the plurality of first openings 14b has a rectangular shape that is long in the second direction Y when seen in the thickness direction Z. There is no particular limitation on the shape of the first openings 14b when seen in the thickness direction Z. The electrode portions 12a are located inside the first openings 14b, respectively. The upper surfaces of the plurality of electrode portions 12a are exposed to the upper side of the semiconductor chip 10. The upper surfaces of the plurality of electrode portions 12a are disposed at the same position as the upper surface of the insulation portion 14 in the thickness direction Z, for example. A second opening 14c that opens upward is formed in the insulation portion 14. At least a part of the third electrode 13 is located inside the second opening 14c. The upper surface of the third electrode 13 is exposed to the upper side of the semiconductor chip 10. The upper surface of the third electrode portion 12a is located at the same position as the upper surface of the insulation portion 14 in the thickness direction Z, for example.

The insulation portion 14 separates the plurality of electrode portions 12a from each other on the upper surface 10b. The insulation portion 14 has a plurality of partition walls 14a. In the first embodiment, the plurality of partition walls 14a extend in the second direction Y. The plurality of partition walls 14a are disposed in the first direction X at intervals. Each of the partition walls 14a is located between the electrode portions 12a arranged in the first direction X. In the first embodiment, the insulation portion 14 has three partition walls 14a. Each of the partition walls 14a separates two of the plurality of electrode portions 12a in the first direction X on the upper surface 10b. Each of the plurality of partition walls 14a has a surface that forms a part of the upper surface 10b. The upper surfaces of the partition walls 14a form a part of the upper surface 10b.

The first conductive member 20 is electrically connected to the semiconductor chip 10. As shown in FIG. 1, the first conductive member 20 is located below the semiconductor chip 10. The first conductive member 20 has electrical conductivity. The first conductive member 20 is made of a metal. The metal forming the first conductive member 20 is, for example, copper (Cu), an alloy containing copper, or the like. The material for forming the first conductive member 20 is not particularly limited as long as it has electrical conductivity. In the first embodiment, the first conductive member 20 has a plate shape with a plate surface facing the thickness direction Z. An upper surface of the first conductive member 20 is electrically bonded to a lower surface of the first electrode 11 via the bonding material 60. A lower surface of the first conductive member 20 is exposed downward from the resin portion 70. The lower surface of the first conductive member 20 forms a part of a lower surface of the semiconductor device 100.

The second conductive member 41 is located on the front side (the +X side) with respect to the semiconductor chip 10 in the first direction X. The second conductive member 41 is located in front of and spaced apart from the first conductive member 20. In the first embodiment, the second conductive member 41 is disposed at the same position in the thickness direction Z as the first conductive member 20. The second conductive member 41 has electrical conductivity. The second conductive member 41 is made of a metal. The metal forming the second conductive member 41 is, for example, copper, an alloy containing copper, or the like. There is no particular limitation on the material for forming the second conductive member 41 as long as it has electrical conductivity. In the first embodiment, the second conductive member 41 is a plate shape with a plate surface facing the thickness direction Z. A lower surface of the second conductive member 41 is exposed downward from the resin portion 70. The lower surface of the second conductive member 41 forms a part of the lower surface of the semiconductor device 100. The second conductive member 41 is electrically connected to the second electrode 12 via the first connection member 30.

As shown in FIG. 2, the third conductive member 42 is located on the front side (the +X side) with respect to the semiconductor chip 10 in the first direction X. The third conductive member 42 is located in front of and spaced apart from the first conductive member 20. In the first embodiment, the third conductive member 42 is disposed at the same position in the thickness direction Z as the first conductive member 20. The third conductive member 42 has electrical conductivity. The third conductive member 42 is made of a metal. The metal forming the third conductive member 42 is, for example, copper, an alloy containing copper, or the like. The material for forming the third conductive member 42 is not particularly limited as long as it has electrical conductivity. In the first embodiment, the third conductive member 42 has a plate shape with a plate surface facing the thickness direction Z. Although not shown in the drawings, a lower surface of the third conductive member 42 is exposed downward from the resin portion 70. The lower surface of the third conductive member 42 forms a part of the lower surface of the semiconductor device 100. The third conductive member 42 is electrically connected to the third electrode 13 via the second connection member 50.

As shown in FIG. 1, the first connection member 30 is located above the semiconductor chip 10. The first connection member 30 is disposed to sandwich the semiconductor chip 10 between the first conductive member 20 and the first connection member 30 in the thickness direction Z. The first connection member 30 is a connection member that electrically connects the semiconductor chip 10 and the second conductive member 41. The first connection member 30 includes a connection member main body 30a and a first film 34. In the first embodiment, the first connection member 30 is configured of the connection member main body 30a and the first film 34. The connection member main body 30a has electrical conductivity. The connection member main body 30a is made of a metal. The metal forming the connection member main body 30a is, for example, copper, an alloy containing copper, or the like. The material for forming the connection member main body 30a is not particularly limited as long as it has electrical conductivity. In the first embodiment, the connection member main body 30a is a sheet metal member. The connection member main body 30a is formed, for example, by pressing a metal plate. A plate surface of the connection member main body 30a faces the thickness direction Z. The connection member main body 30a extends in the first direction X. The connection member main body 30a extends from a position at which it overlaps the semiconductor chip 10 to a position at which it overlaps the second conductive member 41 when seen in the thickness direction Z.

The connection member main body 30a has a first fixing portion 31, a second fixing portion 32, and a bent portion 33. The first fixing portion 31 is a portion that is fixed to the semiconductor chip 10. In the first embodiment, the first fixing portion 31 is fixed to the semiconductor chip 10 by a bonding material 61. The bonding material 61 has electrical conductivity. The bonding material 61 is a material that can electrically bond objects together by attaching the objects to each other in a molten state and then being hardened. In the first embodiment, the bonding material 61 is solder. The first fixing portion 31 has a plate shape with a plate surface perpendicular to the thickness direction Z. A lower surface of the first fixing portion 31 is bonded to the upper surface 10b of the semiconductor chip 10 via the bonding material 61. The lower surface of the first fixing portion 31 is electrically bonded to the plurality of electrode portions 12a via the bonding material 61.

The bonding material 61 is in contact with the upper surface 10b of the semiconductor chip 10. The bonding material 61 is in contact with at least a part of the upper surface of the insulation portion 14 and at least a part of the upper surface of each of the electrode portions 12a. In this embodiment, the bonding material 61 is in contact with the entire upper surfaces of the plurality of partition walls 14a and the entire upper surfaces of the plurality of electrode portions 12a. The bonding material 61 may be in contact with only a part of the upper surface of each of the electrode portions 12a, and may not be in contact with the other part of the upper surface of each of the electrode portions 12a. A wettability of the upper surface of the insulation portion 14 with respect to the bonding material 61 is lower than a wettability of the upper surfaces of the plurality of electrode portions 12a with respect to the bonding material 61. That is, a wettability of the portion of the partition wall 14a that forms the upper surface 10b with respect to the bonding material 61 is lower than a wettability of the portions of the plurality of electrode portions 12a that form the upper surface 10b with respect to the bonding material 61.

In the present disclosure, the term “wettability of a certain object with respect to a bonding material” refers to the wettability of a certain object with respect to the bonding material in a molten state. The wettability may be evaluated, for example, by a wetting balance method or a contact angle method defined in JIS Z 3198-4 of the Japanese Industrial Standards. For example, when the wettability is evaluated by a wetting balance method (a balance method), as a maximum wetting force increases, the wettability becomes higher. For example, when the wettability is evaluated by a contact angle method, as a contact angle is reduced, the wettability becomes higher. The evaluation of wettability may be performed by any known evaluation method other than the above-described methods.

As shown in FIG. 2, the first fixing portion 31 overlaps the semiconductor chip 10 when seen in the thickness direction Z. In the first embodiment, a portion of the first fixing portion 31 on the rear side (the −X side) overlaps the semiconductor chip 10 when seen in the thickness direction Z. The first fixing portion 31 overlaps the entirety of the plurality of electrode portions 12a when seen in the thickness direction Z. The lower surface of the first fixing portion 31 is bonded to the upper surfaces of the plurality of electrode portions 12a via the bonding materials 61. The first fixing portion 31 is electrically connected to the plurality of electrode portions 12a. The first fixing portion 31 protrudes forward (to the +X side) further than the semiconductor chip 10. A dimension in the second direction Y of a front portion of the first fixing portion 31 is smaller than a dimension in the second direction Y of a rear portion of the first fixing portion 31. An edge of the front portion of the first fixing portion 31 on one side (the +Y side) in the second direction Y is located on the other side (the −Y side) in the second direction Y further than an edge of the rear portion of the first fixing portion 31 on the one side in the second direction Y. The front portion of the first fixing portion 31 overlaps the frontmost electrode portion 12a when seen in the thickness direction Z. The rear portion of the first fixing portion 31 overlaps the other three electrode portions 12a when seen in the thickness direction Z.

As shown in FIG. 1, the second fixing portion 32 is a portion that is fixed to the second conductive member 41. In the first embodiment, the second fixing portion 32 is fixed to the second conductive member 41 by a bonding material 62. The bonding material 62 has electrical conductivity. The bonding material 62 is a material that can electrically bond objects together by attaching the objects to each other in a molten state and then being hardened. In the first embodiment, the bonding material 62 is solder. In the first embodiment, the bonding materials 60, 61, and 62 are the same type of solder. At least two of the bonding materials 60, 61, and 62 may be different types of solder. The second fixing portion 32 has a plate shape with a plate surface perpendicular to the thickness direction Z. A lower surface of the second fixing portion 32 is bonded to an upper surface of the second conductive member 41 via the bonding material 62. The second fixing portion 32 is electrically connected to the second conductive member 41. The second fixing portion 32 is located further forward (on the +X side) than the first fixing portion 31. The second fixing portion 32 is located to be lower than the first fixing portion 31.

The bent portion 33 connects the first fixing portion 31 and the second fixing portion 32. The bent portion 33 is bent downward from an end portion of the first fixing portion 31 on the front side (the +X side). The bent portion 33 extends forward and downward from the front side end portion of the first fixing portion 31 and is connected to an end portion of the second fixing portion 32 on the rear side (the −X side).

The first connection member 30 has the first film 34 formed on the surface of the connection member main body 30a. In the first embodiment, the first film 34 is formed on a part of the lower surface of the connection member main body 30a. More specifically, the first film 34 is formed on a portion of the lower surface of the first fixing portion 31 that is located on the front side (the +X side) with respect to the plurality of electrode portions 12a. As shown in FIG. 2, the first film 34 extends in the second direction Y. The first film 34 extends from an edge on one side in the second direction Y to an edge on the other side in the second direction Y of the lower surface of the connection member main body 30a.

The wettability of the surface of the first film 34 with respect to the bonding material 61 is lower than the wettability of the surface of the connection member main body 30a with respect to the bonding material 61. In the first embodiment, the surface of the first film 34 includes a lower surface of the first film 34. The lower surface of the first film 34 forms a part of the lower surface of the first connection member 30. In the first embodiment, the lower surface of the first connection member 30 is formed by a portion of the lower surface of the connection member main body 30a on which the first film 34 is not formed, and the lower surface of the first film 34.

The material for forming the first film 34 is, for example, nickel (Ni), aluminum (Al), stainless steel, a resin, or the like. When the first film 34 is formed of a resin, the resin forming the first film 34 may be the same type of resin as the resin forming the partition wall 14a, or may be a different type of resin from the resin forming the partition wall 14a. The material for forming the first film 34 is not particularly limited as long as the wettability of the surface of the first film 34 with respect to the bonding material 61 is lower than the wettability of the surface of the connection member main body 30a with respect to the bonding material 61. The first film 34 may be an oxide film formed by oxidation of the surface of the connection member main body 30a.

The surface of the first connection member 30 facing the side (the −Z side) on which the semiconductor chip 10 is located in the thickness direction Z, that is, the lower surface, has a first portion 34a and a second portion 31a. In the first embodiment, the first portion 34a is at least a part of the surface of the first film 34. The first portion 34a is the lower surface of the first film 34. The first portion 34a is disposed on the front side (the +X side) of the second portion 31a. In the first embodiment, the first portion 34a is adjacent to the front side of the second portion 31a. In the first embodiment, a rear side (−X side) edge of the first portion 34a is connected to a front side edge of the second portion 31a when seen in the thickness direction Z. The wettability of the first portion 34a with respect to the bonding material 61 is lower than the wettability of the second portion 31a with respect to the bonding material 61. In the example of FIG. 1, the first portion 34a is not in contact with the bonding material 61, but the present invention is not limited thereto. A part of the first portion 34a may be in contact with the bonding material 61. The first portion 34a and the second portion 31a may be arranged in the first direction X with a gap therebetween. In this case, for example, a portion having wettability with respect to the bonding material 61 different from that of each of the first portion 34a and the second portion 31a may be formed between the first portion 34a and the second portion 31a in the first direction X. The portion having the different wettability may be formed by a surface roughness of the connection member main body 30a being different from that of the second portion 31a, or by a film different from the first film 34 being formed on the surface of the connection member main body 30a.

In the first embodiment, the second portion 31a is a part of the surface of the connection member main body 30a. More specifically, the second portion 31a is a part of the lower surface of the first fixing portion 31 that is located on the rear side (the −X side) with respect to the first film 34. The second portion 31a overlaps the semiconductor chip 10 when seen in the thickness direction Z. The second portion 31a overlaps the entirety of the plurality of electrode portions 12a when seen in the thickness direction Z. The second portion 31a is electrically bonded to the plurality of electrode portions 12a by the bonding material 61.

As shown in FIG. 2, the second connection member 50 is located above the semiconductor chip 10. The second connection member 50 is disposed to sandwich the semiconductor chip 10 between the first conductive member 20 and the second connection member 50 in the thickness direction Z. The second connection member 50 is a connection member that electrically connects the semiconductor chip 10 and the third conductive member 42. The second connection member 50 has electrical conductivity. The second connection member 50 is made of a metal. The metal forming the second connection member 50 is, for example, copper or an alloy containing copper. The material for forming the second connection member 50 is not particularly limited as long as it has electrical conductivity. In the first embodiment, the second connection member 50 is a sheet metal member. The second connection member 50 is formed, for example, by pressing a metal plate. The plate surface of the second connection member 50 faces the thickness direction Z. The second connection member 50 extends in the first direction X. The second connection member 50 is arranged on one side (the +Y side) of the first connection member 30 in the second direction Y with a gap therebetween.

The second connection member 50 has a first fixing portion 51, a second fixing portion 52, and a bent portion 53. The first fixing portion 51 is a portion that is fixed to the semiconductor chip 10. In the first embodiment, the first fixing portion 51 is fixed to the semiconductor chip 10 by a bonding material (not shown). The bonding material is the same as the above-described bonding materials 60, 61, and 62. That is, the bonding material is, for example, solder. The first fixing portion 51 is electrically bonded to the third electrode 13 via the bonding material.

The second fixing portion 52 is a portion that is fixed to the third conductive member 42. In the first embodiment, the second fixing portion 52 is fixed to the third conductive member 42 by a bonding material (not shown). The bonding material is the same as the above-described bonding materials 60, 61, and 62. That is, the bonding material is, for example, solder. The second fixing portion 52 is located on the front side (the +X side) with respect to the first fixing portion 51. Although not shown in the drawings, the second fixing portion 52 is located below the first fixing portion 51. The bent portion 53 connects the first fixing portion 51 and the second fixing portion 52. Although not shown in the drawing, the bent portion 53 is bent downward from an end portion of the first fixing portion 51 on the front side (the +X side). The bent portion 53 extends forward and downward from the front side end portion of the first fixing portion 51 and is connected to an end portion of the second fixing portion 52 on the rear side (the −X side).

As shown in FIG. 1, the resin portion 70 covers the semiconductor chip 10, the first conductive member 20, the first connection member 30, the second conductive member 41, the second connection member 50, and the third conductive member 42. The semiconductor chip 10, the first conductive member 20, the first connection member 30, the second conductive member 41, the second connection member 50, and the third conductive member 42 are embedded inside the resin portion 70. The lower surface of the first conductive member 20, the lower surface of the second conductive member 41, and the lower surface of the third conductive member 42 are exposed from the resin portion 70. In the first embodiment, the lower surface of the semiconductor device 100 is configured of the lower surface of the first conductive member 20, the lower surface of the second conductive member 41, the lower surface of the third conductive member 42, and the lower surface of the resin portion 70. The resin portion 70 is formed of, for example, an epoxy resin. The resin forming the resin portion 70 may be a resin other than the epoxy resin.

A worker or the like assembling the semiconductor device 100 applies a paste material containing the powdered bonding material 60 to the upper surface of the first conductive member 20. The worker or the like arrange the semiconductor chip 10 on the upper side of the first conductive member 20 via the applied paste material. The worker or the like applies a paste material containing the powdered bonding material 61 to the upper surface 10b of the semiconductor chip 10, and also applies a paste material containing the powdered bonding material 62 to the upper surface of the second conductive member 41. In addition, the worker or the like applies a paste material containing a powdered bonding material for bonding the second connection members 50 to the upper surface 10b of the semiconductor chip 10 and the upper surface of the third conductive member 42. The worker or the like arrange the first connection member 30 so that the first connection member 30 straddles the upper sides of the semiconductor chip 10 and the second conductive member 41 via the applied paste material. The worker or the like arranges the second connection member 50 so that the second connection member 50 straddles the upper sides of the semiconductor chip 10 and the third conductive member 42 via the applied paste material. The worker or the like heats an assembly in which the first conductive member 20, the second conductive member 41, the third conductive member 42, the semiconductor chip 10, the first connection member 30, and the second connection member 50 are assembled via the paste materials, thereby melting the bonding material contained in each of the paste materials. The molten bonding material adheres to each of the objects and is then hardened, thereby bonding the objects to each other. Each of the paste materials described above in the first embodiment is a cream solder containing powdered solder and a binder such as flux. The binder contained in each of the paste materials is vaporized by heat when the bonding material is melted.

After the objects are bonded to each other using each of the bonding materials, the worker or the like forms the resin portion 70 by placing the assembly in which the objects are bonded to each other in a mold and injecting a resin into the mold. Thus, the semiconductor device 100 is manufactured. In the present disclosure, the term “worker or the like” is not limited to a worker, but may also refer to a device that performs a work. The work performed by the above-described worker or the like may be performed by only the worker, may be performed by only the device, or may be performed by the worker and the device together.

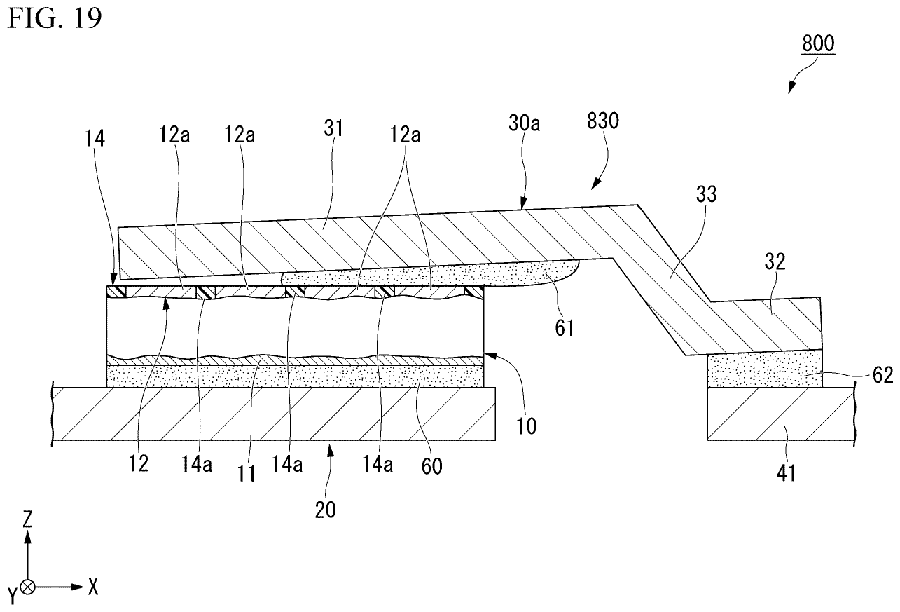

When the semiconductor device 100 is manufactured as described above, the first connection member 30 may be disposed to be inclined with respect to the semiconductor chip 10. FIG. 19 is a cross-sectional view showing a part of a semiconductor device 800 of a comparative example. The resin portion 70 is omitted in FIG. 19. Only a portion of the semiconductor chip 10 is shown in cross section in FIG. 19. In the semiconductor device 800, a first connection member 830 does not have the first film 34. As shown in FIG. 19, the first connection member 830 is disposed to be inclined in the thickness direction Z with respect to the semiconductor chip 10. More specifically, the first connection member 830 is disposed to be inclined with respect to the semiconductor chip 10 so that the portion of the first fixing portion 31 on the front side (the +X side) is located higher than the portion of the first fixing portion 31 on the rear side (the −X side). Therefore, a distance in the thickness direction Z between the first connection member 830 and the semiconductor chip 10 increases from the rear side to the front side. The other configurations of the first connection member 830 are similar to the other configurations of the first connection member 30 in the first embodiment. The other configurations of the semiconductor device 800 are similar to those of the semiconductor device 100 in the first embodiment.

When the first connection member 830 is disposed to be inclined as shown in FIG. 19, the bonding material 61 that melts when the first connection member 830 and the semiconductor chip 10 are bonded to each other easily moves to the side on which a gap between the first connection member 830 and the semiconductor chip 10 is larger, that is, to the front side (the +X side). Furthermore, the wettability of the upper surfaces of the plurality of partition walls 14a with respect to the bonding material 61 is lower than that of the upper surfaces of the plurality of electrode portions 12a. Therefore, even when the molten bonding material 61 that has moved to the front side attempts to spread rearward, the movement of the molten bonding material 61 is likely to be hindered by the upper surfaces of the plurality of partition walls 14a. Therefore, when the first connection member 830 is disposed to be inclined as shown in FIG. 19, the bonding material 61 spreads along the lower surface of the first connection member 830 forward of the semiconductor chip 10. Thus, there are cases in which the bonding material 61 does not spread evenly all over the plurality of electrode portions 12a that form a part of the upper surface 10b of the semiconductor chip 10. The example of FIG. 19 shows a case in which the bonding material 61 is not disposed on the electrode portion 12a located on the rear side (the −X side) among the plurality of electrode portions 12a. In such a case, a connection area between the first connection member 830 and the second electrode 12 of the semiconductor chip 10 becomes small, and thus problems such as an increase in on-resistance and thermal resistance of the semiconductor device 800 may occur.

To address the above problem, according to the first embodiment, the semiconductor device 100 includes the semiconductor chip 10 and the first conductive member 20 electrically connected to the semiconductor chip 10. The semiconductor device 100 includes the second conductive member 41 located on the front side (the first side, the +X side) with respect to the semiconductor chip 10 in the first direction X (the predetermined direction) perpendicular to the thickness direction Z of the semiconductor chip 10. The semiconductor device 100 includes the first connection member 30 that is disposed to sandwich the semiconductor chip 10 between the first conductive member 20 and the first connection member 30 in the thickness direction Z and electrically connects the semiconductor chip 10 and the second conductive member 41. The semiconductor chip 10 includes the first electrode 11 that forms at least a part of the lower surface 10a (the first surface) of the semiconductor chip 10 on the side (the −Z side) on which the first conductive member 20 is located in the thickness direction Z. The semiconductor chip 10 includes the second electrode 12 having the plurality of electrode portions 12a. The semiconductor chip 10 has the partition wall 14a having the upper surface that forms a part of the upper surface 10b (the second surface) of the semiconductor chip 10 on the side (the +Z side) on which the first connection member 30 is located in the thickness direction Z. Each of the plurality of electrode portions 12a has the upper surface that forms a part of the upper surface 10b. The partition wall 14a separates two of the plurality of electrode portions 12a from each other in the first direction X on the upper surface 10b. The surface of the first connection member 30 that faces the side (the −Z side) on which the semiconductor chip 10 is located in the thickness direction Z has the first portion 34a and the second portion 31a. The second portion 31a overlaps the semiconductor chip 10 when seen in the thickness direction Z, and is electrically bonded to the plurality of electrode portions 12a by the bonding material 61. The first portion 34a is arranged on the front side of the second portion 31a. The wettability of the portion of the partition wall 14a that forms the upper surface 10b with respect to the bonding material 61 is lower than the wettability of the portions of the plurality of electrode portions 12a that form the upper surface 10b with respect to the bonding material 61. The wettability of the first portion 34a with respect to the bonding material 61 is lower than the wettability of the second portion 31a with respect to the bonding material 61. Therefore, in the case in which the first connection member 30 is inclined like the first connection member 830 shown in FIG. 19, even when the molten bonding material 61 attempts to move forward, the first portion 34a can curb the bonding material 61 moving forward. Thus, it is possible to curb the molten bonding material 61 leaking forward of the semiconductor chip 10. Therefore, a shortage of the bonding material 61 on the upper surface 10b of the semiconductor chip 10 is curbed, and the bonding material 61 can easily spread evenly on the upper surface 10b of the semiconductor chip 10. In addition, the molten bonding material 61 is likely to spread along the second portion 31a which has higher wettability with respect to the bonding material 61 than the first portion 34a. Therefore, the bonding material 61 can be more easily spread evenly on all the locations at which the plurality of electrode portions 12a are exposed on the upper surface 10b of the semiconductor chip 10. Thus, it is possible to curb the bonding material 61 spreading unevenly on the second electrode 12 of the semiconductor chip 10. Therefore, it is possible to curb the connection area between the first connection member 30 and the second electrode 12 of the semiconductor chip 10 being reduced, and to curb occurrence of problems such as an increase in the on-resistance and thermal resistance of the semiconductor device 100.

According to the first embodiment, the first connection member 30 includes the connection member main body 30a and the first film 34 formed on the surface of the connection member main body 30a. The wettability of the surface of the first film 34 with respect to the bonding material 61 is lower than the wettability of the surface of the connection member main body 30a with respect to the bonding material 61. The first portion 34a is at least a part of the surface of the first film 34. Therefore, the first portion 34a can be easily formed by applying a material that has low wettability with respect to the bonding material 61 to the surface of the connection member main body 30a to form the first film 34.

According to the first embodiment, the bonding material 61 is solder. Therefore, the first connection member 30 can be easily and firmly electrically bonded to the plurality of electrode portions 12a.

Hereinafter, embodiments different from the above-described embodiment will be described. In the following description of each of the embodiments, the same components as those described above in the description of each of the embodiments may be appropriately denoted by the same reference numerals, and description thereof may be omitted. In addition, for portions corresponding to each of the portions of the configuration described above in the description of each of the embodiments, the same names but different symbols will be used to describe differences from the above-described configuration, and descriptions of the similarities to the above-described configuration may be omitted. As for configurations of which descriptions are omitted in each of the following embodiments, configurations similar to those described above in each of the embodiments may be adopted, within the scope of no contradiction.

### Second Embodiment

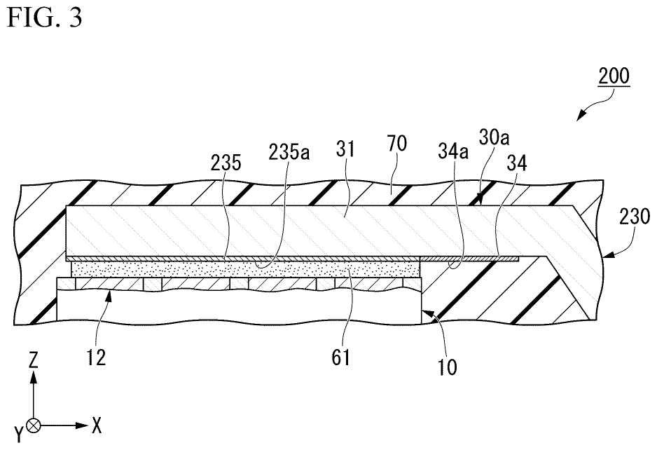

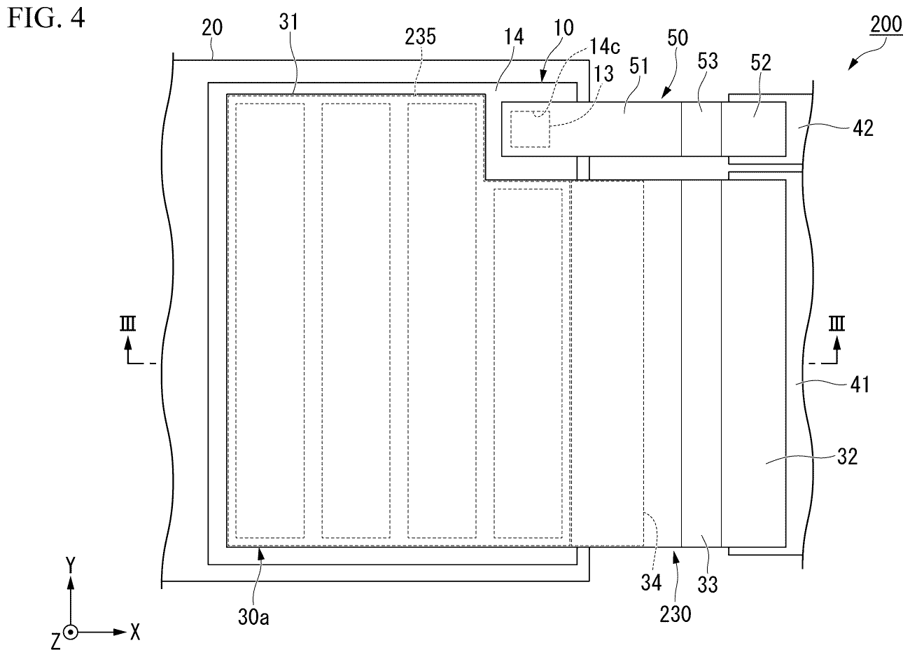

FIG. 3 is a cross-sectional view showing a part of a semiconductor device 200 of a second embodiment and is a cross-sectional view taken along line III-III in FIG. 4. FIG. 4 is a top view showing a part of the semiconductor device 200 of the second embodiment. In FIG. 3, only a portion of the semiconductor chip 10 is shown in cross section, and in FIG. 4, the resin portion 70 is omitted.

As shown in FIG. 3, a first connection member 230 of the second embodiment includes a connection member main body 30a, a first film 34, and a second film 235 formed on the surface of the connection member main body 30a. In the second embodiment, the first connection member 230 is configured of the connection member main body 30a, the first film 34, and the second film 235. In the second embodiment, the second film 235 is formed on a part of the lower surface of the connection member main body 30a. More specifically, the second film 235 is formed on a portion of the lower surface of the first fixing portion 31 that overlaps the plurality of electrode portions 12a when seen in the thickness direction Z. As shown in FIG. 4, in the second embodiment, the second film 235 is formed on an entire portion of the lower surface of the connection member main body 30a that is located on the rear side (the −X side) with respect to the first film 34. The second film 235 is disposed on the rear side of the first film 34. As shown in FIG. 3, in the second embodiment, an edge of the second film 235 on the front side (the +X side) is connected to an edge of the first film 34 on the rear side. The second film 235 is disposed across at least one partition wall 14a in the first direction X when seen in the thickness direction Z. In the second embodiment, the second film 235 is disposed across a plurality of partition walls 14a in the first direction X when seen in the thickness direction Z.

The wettability of the surface of the second film 235 with respect to the bonding material 61 is higher than the wettability of the surface of the connection member main body 30a with respect to the bonding material 61 and the wettability of the surface of the first film 34 with respect to the bonding material 61. In the second embodiment, the surface of the second film 235 includes a lower surface of the second film 235. The lower surface of the second film 235 forms a part of a lower surface of the first connection member 230. In the second embodiment, the lower surface of the first connection member 230 is formed by the lower surface of the first film 34, the lower surface of the second film 235, and a portion of the lower surface of the connection member main body 30a on which the first film 34 and the second film 235 are not formed.

The material for forming the second film 235 is, for example, copper, gold (Au), solder, tin (Sn), or the like. The material for forming the second film 235 is not particularly limited as long as the wettability of the surface of the second film 235 with respect to the bonding material 61 is higher than the wettability of the surface of the connection member main body 30a with respect to the bonding material 61. In the second embodiment, the lower surface of the second film 235 is a second portion 235a. That is, in the second embodiment, the second portion 235a is at least a part of the surface of the second film 235. An edge of the second portion 235a on the front side (the +X side) is connected to an edge of the first portion 34a on the rear side (the −X side). The other configurations of the second portion 235a are similar to the other configurations of the second portion 31a in the first embodiment. The other configurations of the semiconductor device 200 are similar to those of the semiconductor device 100 of the first embodiment.

According to the second embodiment, the first connection member 230 has a second film 235 formed on the surface of the connection member main body 30a. The wettability of the surface of the second film 235 with respect to the bonding material 61 is higher than the wettability of the surface of the connection member main body 30a with respect to the bonding material 61. The second portion 235a is at least a part of a surface of the second film 235. Therefore, by applying a material that has high wettability with respect to the bonding material 61 to the surface of the connection member main body 30a to form the second film 235, it is possible to easily form the second portion 235a that has higher wettability than the surface of the connection member main body 30a. Thus, the molten bonding material 61 can spread more easily along the second portion 235a. Therefore, it is possible to further curb the bonding material 61 spreading unevenly on the second electrode 12 of the semiconductor chip 10.

According to the second embodiment, the second film 235 is disposed across the partition wall 14a in the first direction X (the predetermined direction) when seen in the thickness direction Z. Therefore, the molten bonding material 61 spreads along the second film 235, which makes it easier for the molten bonding material 61 to spread across the partition wall 14a. Thus, it is possible to further curb the bonding material 61 spreading unevenly on the second electrode 12 of the semiconductor chip 10.

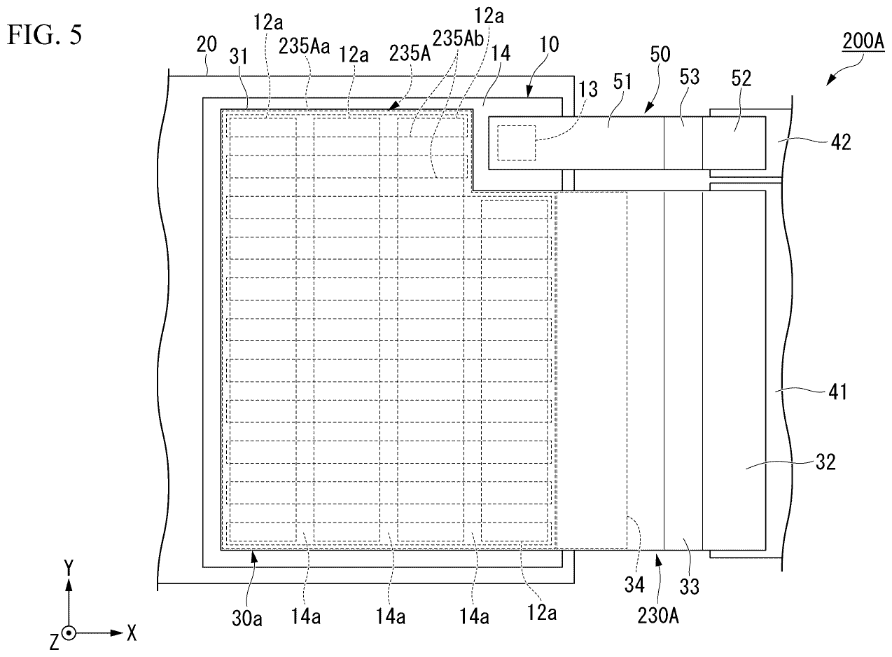

There is no particular limitation on a shape of the second film 235 when seen in the thickness direction Z. The second film 235 may have, for example, a shape like that of a second film 235A shown in FIG. 5. FIG. 5 is a top view of a part of a semiconductor device 200A according to a first modified example of the second embodiment. In FIG. 5, the resin portion 70 is omitted. As shown in FIG. 5, the second film 235A of the first connection member 230A has a frame portion 235Aa and a plurality of extension portions 235Ab. The frame portion 235Aa is a frame-shaped portion formed along an outer edge of a portion of the first fixing portion 31 that is located on the rear side (the −X side) with respect to the first film 34 when seen in the thickness direction Z. The plurality of extension portions 235Ab are located inside the frame portion 235Aa when seen in the thickness direction Z. The plurality of extension portions 235Ab extend in the first direction X from an edge of the frame portion 235Aa on the rear side to an edge thereof on the front side (the +X side). The plurality of extension portions 235Ab are arranged at intervals in the second direction Y. Each of the extension portions 235Ab straddles at least one partition wall 14a in the first direction X when seen in the thickness direction Z. In the first connection member 230A of the semiconductor device 200A, the lower surface of the second film 235A also is the second portion.

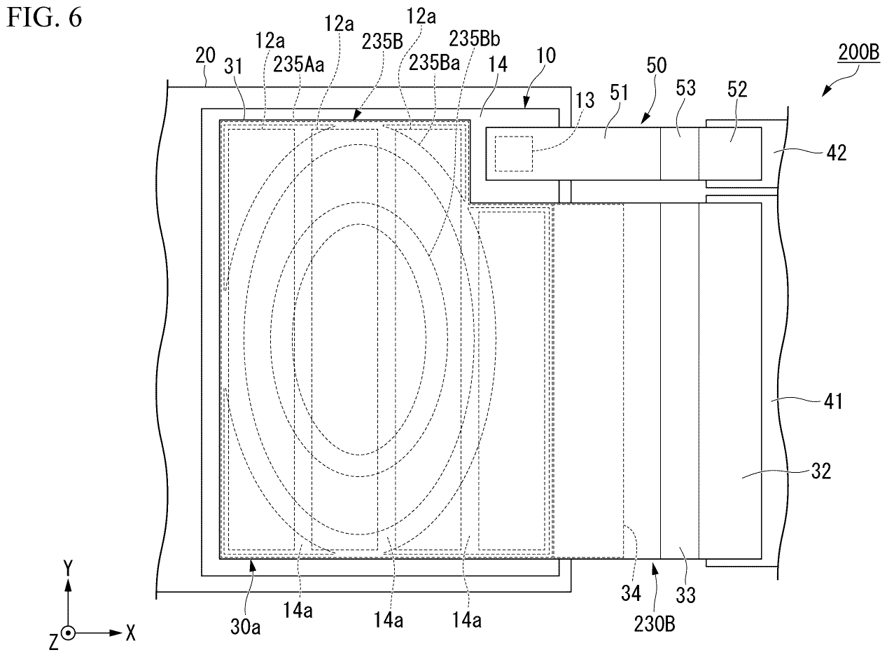

The second film 235 may have, for example, a shape like a second film 235B shown in FIG. 6. FIG. 6 is a top view of a part of a semiconductor device 200B according to a second modified example of the second embodiment. In FIG. 6, the resin portion 70 is omitted. As shown in FIG. 6, the second film 235B of a first connection member 230B has a frame portion 235Aa, a first annular portion 235Ba, and a second annular portion 235Bb. The first annular portion 235Ba and the second annular portion 235Bb are located inside the frame portion 235Aa when seen in the thickness direction Z. The first annular portion 235Ba and the second annular portion 235Bb have an elliptical annular shape that is long in the second direction Y when seen in the thickness direction Z. A part of an outer edge of the first annular portion 235Ba is connected to an inner edge of the frame portion 235Aa. The second annular portion 235Bb is located inside the first annular portion 235Ba when seen in the thickness direction Z. The first annular portion 235Ba and the second annular portion 235Bb are concentric elliptical annular portions when seen in the thickness direction Z. In the first connection member 230B of the semiconductor device 200B as well, a lower surface of the second film 235B is the second portion.

### Third Embodiment

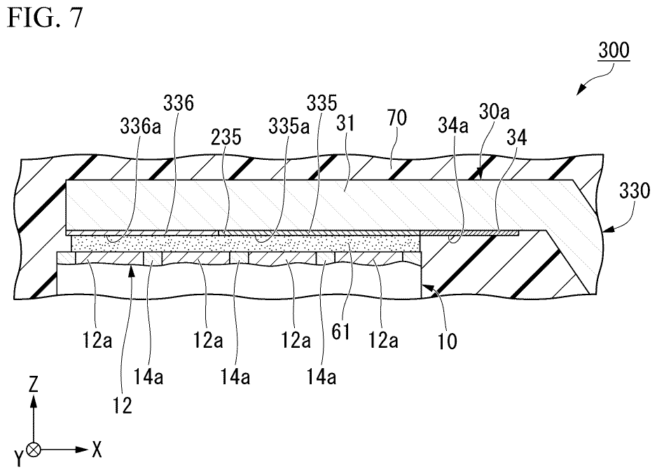

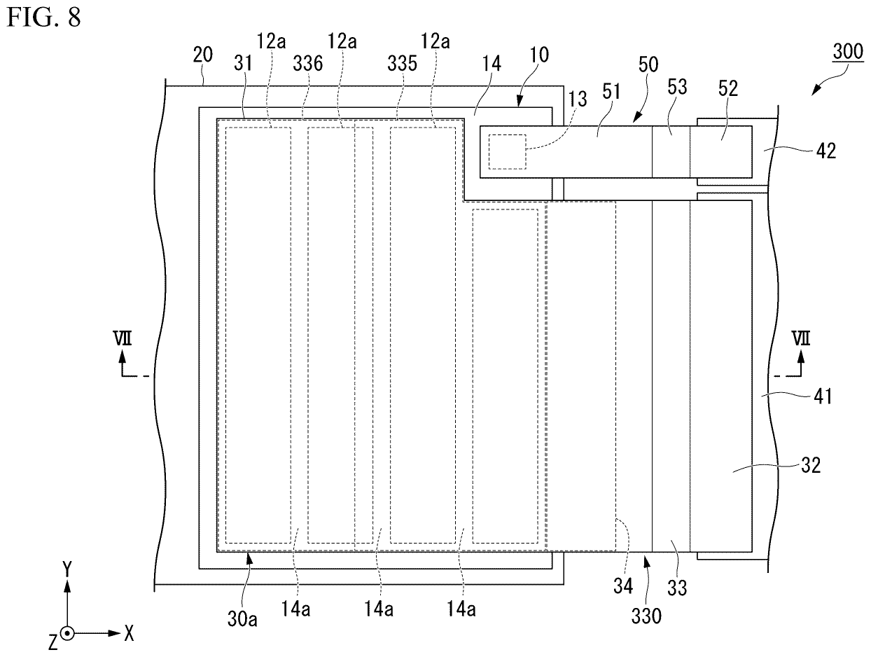

FIG. 7 is a cross-sectional view showing a part of a semiconductor device 300 of a third embodiment and is a cross-sectional view taken along line VII-VII in FIG. 8. FIG. 8 is a top view showing a part of the semiconductor device 300 of the third embodiment. In FIG. 7, only a part of the semiconductor chip 10 is shown in cross section, and in FIG. 8, the resin portion 70 is omitted.

As shown in FIG. 7, in the semiconductor device 300, a first connection member 330 includes a first film 34, a second film 335, and a third film 336. The first film 34, the second film 335, and the third film 336 are formed on the surface of the connection member main body 30a. The second film 335 and the third film 336 are formed on a portion of the lower surface of the first fixing portion 31 that is located on the rear side (the −X side) with respect to the first film 34. The second film 335 and the third film 336 are electrically bonded to the plurality of electrode portions 12a by the bonding material 61. The third film 336 is arranged on the rear side of the second film 335. As shown in FIG. 8, each of the second film 335 and the third film 336 is formed from an edge of the lower surface of the first fixing portion 31 on one side in the second direction Y to an edge thereof on the other side in the second direction Y. The second film 335 is formed on an entire portion of lower surface of the first fixing portion 31 that is located on the rear side with respect to the first film 34 and on the front side (on the +X side) of the third film 336. The third film 336 is formed on an entire portion of the lower surface of the first fixed part 31 that is located on the rear side with respect to the second film 335. An edge of the third film 336 on the front side is connected to an edge of the second film 335 on the rear side. The third film 336 is disposed in the first direction X across the partition wall 14a that is located at the rearmost side among the plurality of partition walls 14a when seen in the thickness direction Z. The second film 335 is similar to the second film 235 in the second embodiment, except that a range in which the second film 335 is formed on the surface of the connection member main body 30a is different.

The wettability of the surface of the third film 336 with respect to the bonding material 61 is higher than the wettability of the surface of the connection member main body 30a with respect to the bonding material 61, the wettability of the surface of the first film 34 with respect to the bonding material 61, and the wettability of the surface of the second film 335 with respect to the bonding material 61. The material for forming the third film 336 is, for example, copper, gold, solder, tin, or the like. The material for forming the third film 336 is not particularly limited as long as the wettability of the surface of the third film 336 with respect to the bonding material 61 is higher than the wettability of the surface of the second film 335 with respect to the bonding material 61. In the third embodiment, the surface of the third film 336 includes a lower surface of the third film 336. As shown in FIG. 7, the lower surface of the third film 336 forms a part of the lower surface of the first connection member 330. In the third embodiment, the lower surface of the first connection member 330 includes a portion of the lower surface of the connection member main body 30a on which the first film 34, the second film 335, and the third film 336 are not formed. The lower surface of the first connection member 330 is formed by the above-described portion, the lower surface of the first film 34, the lower surface of the second film 335, and the lower surface of the third film 336.

In the third embodiment, a surface of the first connection member 330 that faces the side on which the semiconductor chip 10 is located in the thickness direction Z, that is, the lower surface, has a first portion 34a, a second portion 335a, and a third portion 336a. In the third embodiment, the second portion 335a is a lower surface of the second film 335. The other configurations of the second portion 335a are similar to the other configurations of the second portion 235a in the second embodiment.

The third portion 336a overlaps the semiconductor chip 10 when seen in the thickness direction Z, and is electrically bonded to the plurality of electrode portions 12a by the bonding material 61. In the third embodiment, the third portion 336a is at least a part of a surface of the third film 336. The third portion 336a is a lower surface of the third film 336. The third portion 336a is located on the rear side (the −X side) with respect to the second portion 335a. The third portion 336a is adjacent to the rear side of the second portion 335a. An edge of the third portion 336a on the front side (the +X side) is connected to an edge of the second portion 335a on the rear side. The wettability of the third portion 336a with respect to the bonding material 61 is higher than that of the second portion 335a with respect to the bonding material 61. The third portion 336a is disposed in the first direction X across the partition wall 14a that is located at the rearmost side among the plurality of partition walls 14a when seen in the thickness direction Z. The other configurations of the semiconductor device 300 are similar to the other configurations of the semiconductor device 200 of the second embodiment.

According to the third embodiment, the semiconductor chip 10 has a plurality of partition walls 14a disposed at intervals in the first direction X (the predetermined direction). A surface of the first connection member 330 that faces the side (the −Z side) on which the semiconductor chip 10 is located in the thickness direction Z has the third portion 336a located on the rear side (the second side, the −X side) with respect to the second portion 335a. The wettability of the third portion 336a with respect to the bonding material 61 is higher than that of the second portion 335a with respect to the bonding material 61. The third portion 336a is disposed in the first direction X across the partition wall 14a that is located at the rearmost side among the plurality of partition walls 14a when seen in the thickness direction Z. Therefore, the molten bonding material 61 can be easily spread onto the rearmost electrode portion 12a along the third portion 336a which has the higher wettability with respect to the bonding material 61 than the second portion 335a. Thus, it is possible to further curb the bonding material 61 spreading unevenly on the second electrodes 12 of the semiconductor chip 10.

### Fourth Embodiment

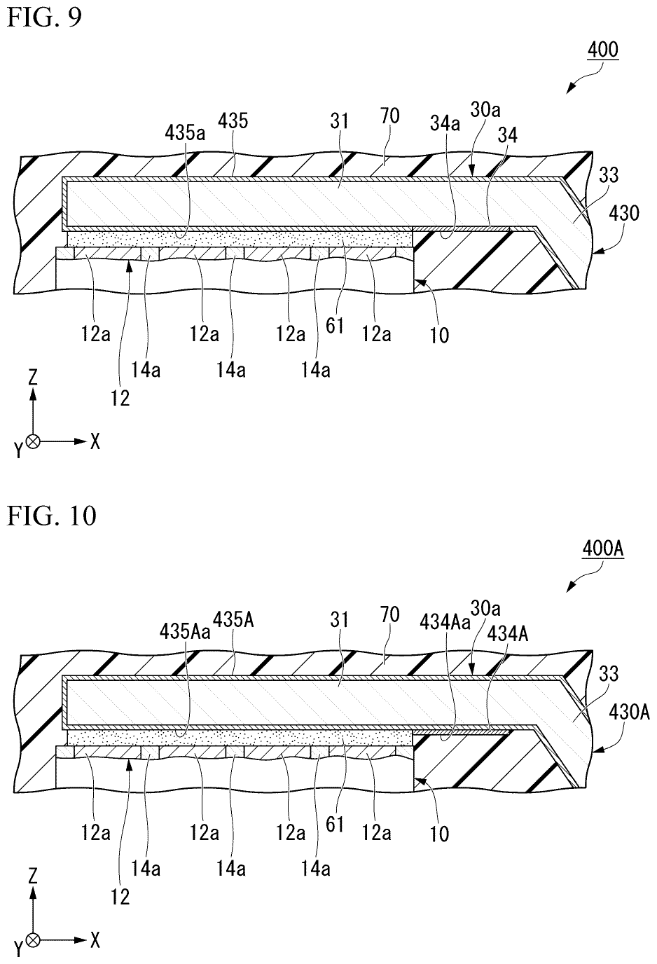

FIG. 9 is a cross-sectional view showing a part of a semiconductor device 400 according to a fourth embodiment. In FIG. 9, only a part of the semiconductor chip 10 is shown in cross section. As shown in FIG. 9, in a first connection member 430 of the semiconductor device 400, a second film 435 is formed on the entire surface of the connection member main body 30a except for a portion on which the first film 34 is formed. The other configurations of the second film 435 are similar to the other configurations of the second film 235 in the second embodiment. In the fourth embodiment, a portion of a lower surface of the second film 435 formed on the first fixing portion 31 that is located on the rear side (the −X side) with respect to the first film 34 is a second portion 435a. The other configurations of the second portion 435a are similar to the other configurations of the second portion 31a in the first embodiment. The other configurations of the semiconductor device 400 are similar to those of the semiconductor device 200 of the second embodiment.

FIG. 10 is a cross-sectional view showing a part of a semiconductor device 400A according to a modified example of the fourth embodiment. In FIG. 10, only a part of the semiconductor chip 10 is shown in cross section. As shown in FIG. 10, in the semiconductor device 400A, a second film 435A is formed on the entire surface of the connection member main body 30a. The other configurations of the second film 435A are similar to those of the second film 435 in the fourth embodiment. In the semiconductor device 400A, a first film 434A is formed on a surface of the second film 435A. The first film 434A is formed on a portion of a lower surface of the second film 435A that is located on the front side (the +X side) of the semiconductor chip 10. The first film 434A is similar to the first film 34 in the first embodiment, except that it is formed on the surface of the second film 435A.

At least a part of the surface of the first film 434A is a first portion 434Aa. The first portion 434Aa is a lower surface of the first film 434A. At least a part of a surface of the second film 435A formed on the first fixing portion 31 is a second portion 435Aa. The second portion 435Aa is similar to the second portion 435a in the fourth embodiment. The other configurations of the first portion 434Aa are similar to the other configurations of the first portion 34a in the first embodiment.

According to the modified example of the fourth embodiment, a first connection member 430A has a connection member main body 30a, a first film 434A, and a second film 435A formed on the entire surface of the connection member main body 30a. The first film 434A is formed on the surface of the second film 435A. The wettability of the surface of the first film 434A with respect to the bonding material 61 is lower than the wettability of the surface of the connection member main body 30a with respect to the bonding material 61. The wettability of the surface of the second film 435A with respect to the bonding material 61 is higher than that of the surface of the connection member main body 30a with respect to the bonding material 61. The first portion 434Aa is at least a part of the surface of the first film 434A. The second portion 435Aa is at least a part of the surface of the second film 435A. Therefore, the first portion 434Aa and the second portion 435Aa can be easily formed by forming the second film 435A over the entire surface of the connection member main body 30a and then forming the first film 434A on the surface of the second film 435A.

### Fifth Embodiment

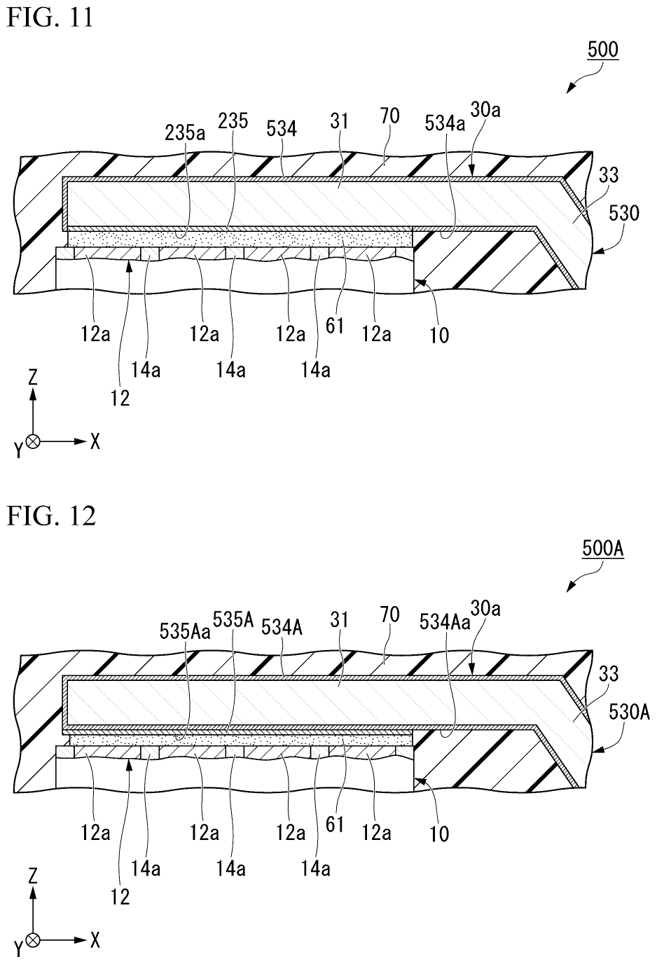

FIG. 11 is a cross-sectional view showing a part of a semiconductor device 500 according to a fifth embodiment. In FIG. 11, only a part of the semiconductor chip 10 is shown in cross section. As shown in FIG. 11, in a first connection member 530 of the semiconductor device 500, a first film 534 is formed on the entire surface of the connection member main body 30a except for a portion on which the second film 235 is formed. The other configurations of the first film 534 are similar to the other configurations of the first film 34 in the first embodiment. In the fifth embodiment, a portion of a lower surface of the first film 534 formed on the first fixing portion 31 that is located on the front side (the +X side) of the second film 235 is a first portion 534a. The other configurations of the first portion 534a are similar to the other configurations of the first portion 34a in the first embodiment. The other configurations of the semiconductor device 500 are similar to the other configurations of the semiconductor device 200 in the second embodiment.

FIG. 12 is a cross-sectional view showing a part of a semiconductor device 500A according to a modified example of the fifth embodiment. In FIG. 12, only a part of the semiconductor chip 10 is shown in cross section. In FIG. 12, in the semiconductor device 500A, a first film 534A is formed on the entire surface of the connection member main body 30a. The other configurations of the first film 534A are similar to the other configurations of the first film 534 in the fifth embodiment. In the semiconductor device 500A, the second film 535A is formed on a surface of the first film 534A. The second film 535A is formed on a portion of a lower surface of the first film 534A that overlaps the semiconductor chip 10 when seen in the thickness direction Z. The second film 535A is similar to the second film 235 in the second embodiment, except that it is formed on the surface of the first film 534A.

At least a part of the surface of the second film 535A is a second portion 535Aa. The second portion 535Aa is a lower surface of the second film 535A. At least a part of the surface of the first film 534A is a first portion 534Aa. The first portion 534Aa is similar to the first portion 534a in the fifth embodiment. The other configurations of the second portion 535Aa are similar to the other configurations of the second portion 235a in the second embodiment.

According to the modified example of the fifth embodiment, the first connection member 530A has the connection member main body 30a, the first film 534A formed on the entire surface of the connection member main body 30a, and the second film 535A formed on the surface of the first film 534A. The wettability of the surface of the first film 534A with respect to the bonding material 61 is lower than the wettability of the surface of the connection member main body 30a with respect to the bonding material 61. The wettability of the surface of the second film 535A with respect to the bonding material 61 is higher than the wettability of the surface of the connection member main body 30a with respect to the bonding material 61. The first portion 534Aa is at least a part of the surface of the first film 534A. The second portion 535Aa is at least a part of the surface of the second film 535A. Therefore, the first portion 534Aa and the second portion 535Aa can be easily formed by forming the first film 534A over the entire surface of the connection member main body 30a and then forming the second film 535A on the surface of the first film 534A.

### Sixth Embodiment

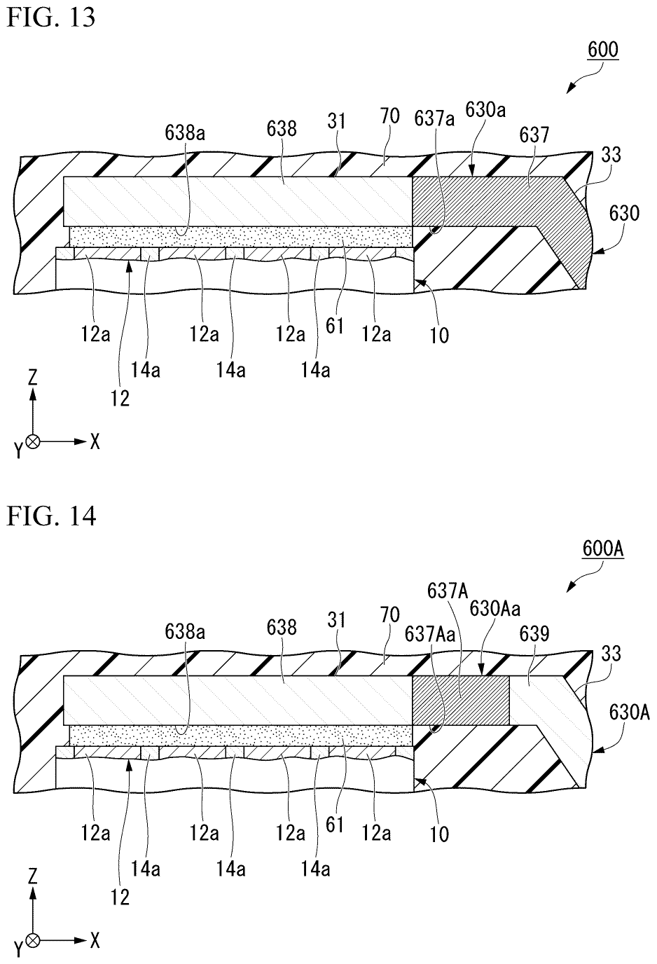

FIG. 13 is a cross-sectional view showing a part of a semiconductor device 600 according to a sixth embodiment. Only a part of the semiconductor chip 10 is shown in cross section in FIG. 13. As shown in FIG. 13, a first connection member 630 of the semiconductor device 600 has a connection member main body 630a. The connection member main body 630a has a first member 637 and a second member 638 bonded to the first member 637. In the sixth embodiment, the connection member main body 630a of the first connection member 630 is formed by bonding the first member 637 and the second member 638 to each other. A shape of the connection member main body 630a is similar to the shape of the connection member main body 30a in the first embodiment. In the sixth embodiment, the first connection member 630 is formed of the connection member main body 630a. Although not shown in the drawing, the connection member main body 630a extends from a position at which it overlaps the semiconductor chip 10 to a position at which it overlaps the second conductive member 41 when seen in the thickness direction Z, similar to the connection member main body 30a in the first embodiment shown in FIG. 2. The second member 638 is located above the semiconductor chip 10. The first member 637 is bonded to an end portion of the second member 638 on the front side (the +X side). The first fixing portion 31 of the connection member main body 630a is formed by a part of the first member 637 and the second member 638. The bent portion 33 of the connection member main body 630a is formed by a part of the first member 637. Although not shown in the drawings, the second fixing portion 32 of the connection member main body 630a is formed by a part of the first member 637. A lower surface of the first connection member 630 is formed by a lower surface of the first member 637 and a lower surface of the second member 638. The first member 637 and the second member 638 are electrically bonded to each other by, for example, welding. A method of bonding the first member 637 and the second member 638 is not particularly limited as long as the first member 637 and the second member 638 are electrically bonded to each other. A bonding surface between the first member 637 and the second member 638 is disposed at a position at which it overlaps the edge of the semiconductor chip 10 on the front side (the +X side) when seen in the thickness direction Z. The bonding surface between the first member 637 and the second member 638 is perpendicular to the first direction X.

The wettability of the surface of the first member 637 with respect to the bonding material 61 is lower than the wettability of the surface of the second member 638 with respect to the bonding material 61. The first member 637 is made of a metal. The metal forming the first member 637 is, for example, nickel, aluminum, stainless steel, or the like. The second member 638 is made of a metal. For example, the metal forming the second member 638 is copper, an alloy containing copper, or the like.

A part of the surface of the first member 637 is a first portion 637a. The first portion 637a is a lower surface of a portion of the first member 637 that forms the first fixing portion 31. A part of the surface of the second member 638 is a second portion 638a. The second portion 638a is the lower surface of the second member 638. The other configurations of the first portion 637a are similar to the other configurations of the first portion 34a in the first embodiment. The other configurations of the second portion 638a are similar to other configurations of the second portion 31a in the first embodiment. The other configurations of the semiconductor device 600 are similar to other configurations of the semiconductor device 100 in the first embodiment.

According to the sixth embodiment, the first connection member 630 has the connection member main body 630a that extends from the position at which it overlaps the semiconductor chip 10 to the position at which it overlaps the second conductive member 41 when seen in the thickness direction Z. The connection member main body 630a has a first member 637 and a second member 638 bonded to the first member 637. The wettability of the surface of the first member 637 with respect to the bonding material 61 is lower than the wettability of the surface of the second member 638 with respect to the bonding material 61. The first portion 637a is a part of a surface of the first member 637. The second portion 638a is a part of a surface of the second member 638. Therefore, the first portion 637a and the second portion 638a can be formed without forming a film on the surface of the connection member main body 630a.

According to the sixth embodiment, the first member 637 is bonded to an end portion of the second member 638 on the front side (the first side, the +X side). Therefore, the first portion 637a and the second portion 638a can be easily formed by bonding the first member 637 and the second member 638 in the first direction X.

FIG. 14 is a cross-sectional view showing a part of a semiconductor device 600A according to a first modified example of the sixth embodiment. Only a part of the semiconductor chip 10 is shown in cross section in FIG. 14. As shown in FIG. 14, in the semiconductor device 600A, a first connection member 630A has a connection member main body 630Aa. The connection member main body 630Aa has a first member 637A, a second member 638, and a third member 639. The connection member main body 630Aa of the first connection member 630A is formed by bonding the first member 637A, the second member 638, and the third member 639 to each other. A shape of the connection member main body 630Aa is similar to the shape of the connection member main body 30a in the first embodiment. The first connection member 630A is formed of the connection member main body 630Aa. Although not shown, the connection member main body 630Aa, like the connection member main body 630a, extends from a position at which it overlaps the semiconductor chip 10 to a position at which it overlaps the second conductive member 41 when seen in the thickness direction Z. The first member 637A is bonded to an end portion of the second member 638 on the front side (the +X side). The third member 639 is bonded to an end portion of the first member 637A on the front side. The first fixing portion 31 of the connection member main body 630Aa is formed by the first member 637A, the second member 638, and a part of the third member 639. The bent portion 33 of the connection member main body 630Aa is formed by a part of the third member 639. Although not shown in the drawings, the second fixing portion 32 of the connection member main body 630Aa is formed by a part of the third member 639.

The lower surface of the first connection member 630A is formed by a lower surface of the first member 637A, a lower surface of the second member 638, and a lower surface of the third member 639. The first member 637A and the second member 638 are electrically bonded to each other by, for example, welding. A method of bonding the first member 637A and the second member 638 is not particularly limited as long as the first member 637A and the second member 638 are electrically connected to each other. The first member 637A and the third member 639 are electrically bonded to each other by, for example, welding. A method of bonding the first member 637A and the third member 639 is not particularly limited as long as the first member 637A and the third member 639 are electrically connected to each other. The lower surface of the first member 637A is a first portion 637Aa. The other configurations of the first member 637A are similar to the other configurations of the first member 637 in the sixth embodiment. The material for forming the third member 639 is similar to the material for forming the second member 638. The material for forming the third member 639 may be different from the material for forming the second member 638. The other configurations of the semiconductor device 600A are similar to those of the semiconductor device 600 in the sixth embodiment.

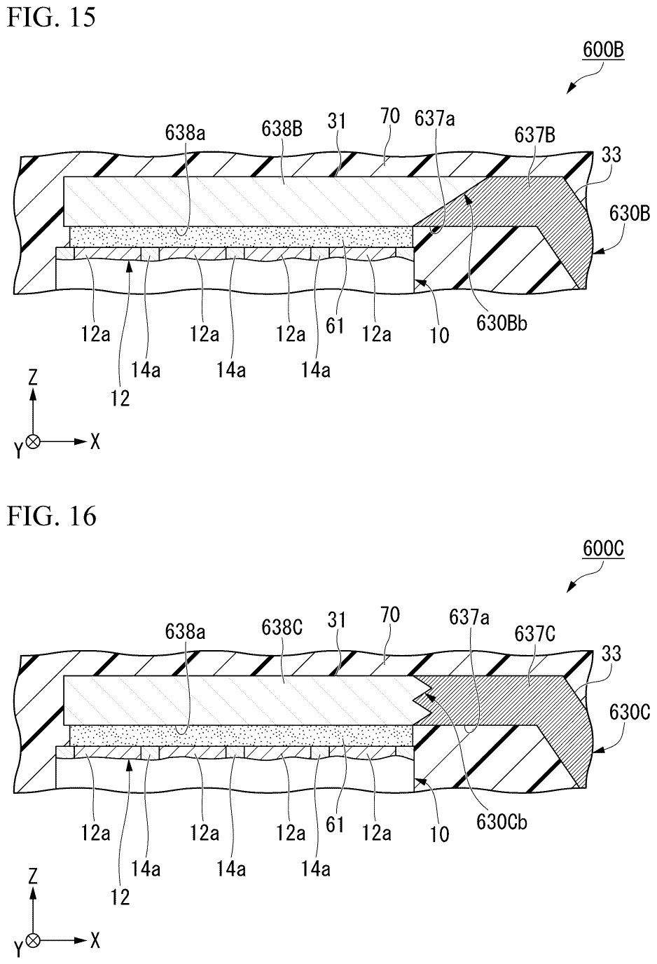

FIG. 15 is a cross-sectional view showing a part of a semiconductor device 600B according to a second modified example of the sixth embodiment. In FIG. 15, only a part of the semiconductor chip 10 is shown in cross section. As shown in FIG. 15, in a first connection member 630B of the semiconductor device 600B, a bonding surface 630Bb at which a first member 637B and a second member 638B are bonded to each other is inclined in the first direction X with respect to a plane perpendicular to the first direction X. In other words, the bonding surface 630Bb has a portion that is inclined with respect to the plane perpendicular to the first direction X. The bonding surface 630Bb of the first member 637B is an inclined surface that is directed upward toward the rear side (the −X side). The bonding surface 630Bb of the second member 638B is an inclined surface that is directed downward toward the front side (the +X side). The other configurations of the first member 637B are similar to the other configurations of the first member 637 in the sixth embodiment. The other configurations of the second member 638B are similar to the other configurations of the second member 638 in the sixth embodiment. The other configurations of the semiconductor device 600B are similar to the other configurations of the semiconductor device 600.

According to the second modified example of the sixth embodiment, the bonding surface 630Bb at which the first member 637B and the second member 638B are bonded to each other has a portion that is inclined with respect to the plane perpendicular to the first direction X (the predetermined direction). Therefore, an area of the bonding surface 630Bb can be made larger than when the bonding surface 630Bb is a surface perpendicular to the first direction X. Thus, the first member 637B and the second member 638B can be bonded more firmly. The bonding surface 630Bb may be inclined to the side opposite to the inclination shown in FIG. 15 in the first direction X. In other words, the bonding surface 630Bb of the first member 637B may be an inclined surface that is directed downward toward the rear side (the −X side) and the bonding surface 630Bb of the second member 638B may be an inclined surface that is directed upward toward the front side (the +X side).

FIG. 16 is a cross-sectional view showing a part of a semiconductor device 600C according to a third modified example of the sixth embodiment. In FIG. 16, only a part of the semiconductor chip 10 is shown in cross section. As shown in FIG. 16, in a first connection member 630C of the semiconductor device 600C, a bonding surface 630Cb at which a first member 637C and a second member 638C are bonded to each other has a zigzag shape when seen in the second direction Y. More specifically, the bonding surface 630Cb is formed by alternately connecting portions directed downward to the front side (the +X side) and portions directed upward toward the front side in the thickness direction Z. In this way, the bonding surface 630Cb has a portion that is inclined with respect to a plane perpendicular to the first direction X. The other configurations of the first member 637C are similar to the other configurations of the first member 637 in the sixth embodiment. The other configurations of the second member 638C are similar to the other configurations of the second member 638 in the sixth embodiment. The other configurations of the semiconductor device 600C are similar to the other configurations of the semiconductor device 600.

According to the third modified example of the sixth embodiment, the bonding surface 630Cb at which a first member 637C and a second member 638C are bonded to each other has a portion that is inclined with respect to a plane perpendicular to the first direction X (the predetermined direction). Therefore, an area of the bonding surface 630Cb can be made larger than when the bonding surface 630Cb is a surface perpendicular to the first direction X. Thus, the first member 637C and the second member 638C can be bonded more firmly. Furthermore, since the bonding surface 630Cb has a zigzag shape when seen in the second direction Y, the shape of the bonding surface 630Cb is more complex than when the bonding surface 630Cb is formed as a single inclined surface. Therefore, the first member 637C and the second member 638C can be bonded more firmly.

### Seventh Embodiment

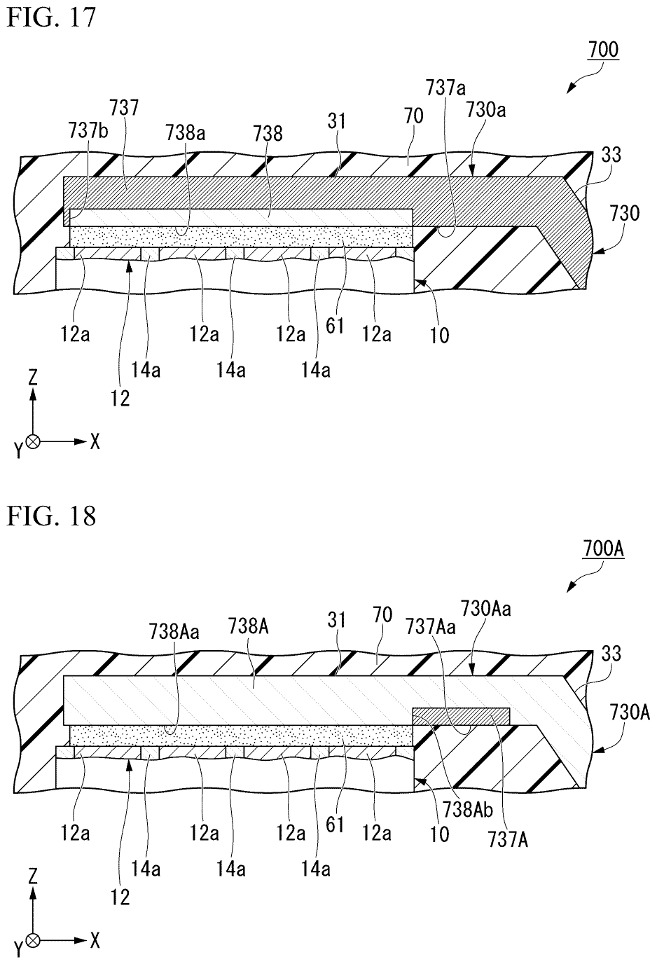

FIG. 17 is a cross-sectional view showing a part of a semiconductor device 700 according to a seventh embodiment. In FIG. 17, only a part of the semiconductor chip 10 is shown in cross section. As shown in FIG. 17, a first connection member 730 of the semiconductor device 700 has a connection member main body 730a. The connection member main body 730a has a first member 737 and a second member 738. A shape of the first member 737 is similar to the shape of the connection member main body 30a of the first embodiment, except that a first recessed portion 737b is formed. The first member 737 has the first recessed portion 737b that opens to the side on which the semiconductor chip 10 is located, that is, the lower side, in the thickness direction Z. The first recessed portion 737b is recessed upward from a lower surface of the first member 737. The first recessed portion 737b overlaps the semiconductor chip 10 when seen in the thickness direction Z. The first recessed portion 737b overlaps the entirety of the plurality of electrode portions 12a when seen in the thickness direction Z. The material for forming the first member 737 is similar to the material for forming the first member 637 in the sixth embodiment. The wettability of the surface of the first member 737 with respect to the bonding material 61 is lower than the wettability of the surface of the second member 738 with respect to the bonding material 61.

The second member 738 is embedded in the first recessed portion 737b. A shape of the second member 738 is similar to a shape of the inside of the first recessed portion 737b. The second member 738 is electrically bonded to the first member 737 by, for example, welding. A method of bonding the first member 737 and the second member 738 is not particularly limited as long as the first member 737 and the second member 738 are electrically bonded to each other. The material for forming the second member 738 is the same as the material for forming the second member 638 in the sixth embodiment.

The connection member main body 730a is formed by bonding the first member 737 and the second member 738 to each other. The shape of the connection member main body 730a is similar to the shape of the connection member main body 30a in the first embodiment. The first connection member 730 is formed of the connection member main body 730a. The first fixing portion 31 of the connection member main body 730a is formed by a part of the first member 737 and a second member 738. A portion of the connection member main body 730a other than the first fixing portion 31 is formed by the first member 737.

At least a part of the surface of the first member 737 is a first portion 737a. The first portion 737a is a portion located on the front side (the +X side) with respect to the first recessed portion 737b on a lower surface of a portion of the first member 737 that forms the first fixing portion 31. The other configurations of the first portion 737a are similar to the other configurations of the first portion 637a in the sixth embodiment. At least a part of the surface of the second member 738 is a second portion 738a. The second portion 738a is a lower surface of the second member 738. The other configurations of the second portion 738a are similar to the other configurations of the second portion 638a in the sixth embodiment. The other configurations of the semiconductor device 700 are similar to the other configurations of the semiconductor device 600 of the sixth embodiment.

According to the seventh embodiment, the first member 737 has the first recessed portion 737b that opens toward the side (the lower side) on which the semiconductor chip 10 is located in the thickness direction Z. The second member 738 is embedded in the first recessed portion 737b. Therefore, a required volume of the second member 738 can be made smaller than in a case in which the first member 737 and the second member 738 are bonded in the first direction X to respectively form the first portion 737a and the second portion 738a. Thus, even when a material that is more expensive than the material used to form the first member 737 is used to form the second member 738, an increase in the cost of manufacturing the first connection member 730 can be curbed. Compared to the case in which the first member 737 and the second member 738 are bonded in the first direction X, the strength of the first connection member 730 can be improved. Furthermore, a bonding area between the first member 737 and the second member 738 can be made larger than in the case in which the first member 737 and the second member 738 are bonded in the first direction X. Therefore, bonding strength between the first member 737 and the second member 738 can be improved.

FIG. 18 is a cross-sectional view showing a part of a semiconductor device 700A according to a modified example of the seventh embodiment. In FIG. 18, only a part of the semiconductor chip 10 is shown in cross section. As shown in FIG. 18, a first connection member 730A of the semiconductor device 700A has a connection member main body 730Aa. The connection member main body 730Aa has a first member 737A and a second member 738A. A shape of the second member 738A is similar to the shape of the connection member main body 30a of the first embodiment, except that a second recessed portion 738Ab is formed. The second member 738A has the second recessed portion 738Ab that opens to the side on which the semiconductor chip 10 is located in the thickness direction Z, that is, to the lower side. The second recessed portion 738Ab is recessed upward from a lower surface of the second member 738A. The second recessed portion 738Ab is located on the front side (the +X side) with respect to the semiconductor chip 10. An edge of the second recessed portion 738Ab the rear side (the −X side) overlaps the edge of the semiconductor chip 10 on the front side when seen in the thickness direction Z. The material for forming the second member 738A is the same as the material for forming the second member 638 in the sixth embodiment.

The first member 737A is embedded in the second recessed portion 738Ab. A shape of the first member 737A is similar to a shape of the inside of the second recessed portion 738Ab. The first member 737A is electrically bonded to the second member 738A by, for example, welding. A method of bonding the first member 737A and the second member 738A is not particularly limited as long as the first member 737A and the second member 738A are electrically bonded to each other. The material for forming the first member 737A is similar to the material for forming the first member 637 in the sixth embodiment. The wettability of the surface of the first member 737A with respect to the bonding material 61 is lower than the wettability of the surface of the second member 738A with respect to the bonding material 61.

The connection member main body 730Aa is formed by bonding the first member 737A and the second member 738A to each other. The shape of the connection member main body 730Aa is similar to the shape of the connection member main body 30a in the first embodiment. The first connection member 730A is formed of the connection member main body 730Aa. The first fixing portion 31 of the connection member main body 730Aa is formed by the first member 737A and a part of the second member 738. A portion of the connection member main body 730Aa other than the first fixing portion 31 is formed by the second member 738A.

At least a part of the surface of the first member 737A is a first portion 737Aa. The first portion 737Aa is a lower surface of the first member 737A. The other configurations of the first portion 737Aa are similar to the other configurations of the first portion 637a in the sixth embodiment. At least a part of the surface of the second member 738 is a second portion 738Aa. The second portion 738Aa is a portion located on the rear side (the −X side) of the second recessed portion 738Ab on the lower surface of the portion of the second member 738A that forms the first fixing portion 31. The other configurations of the second portion 738Aa are similar to the other configurations of the second portion 638a in the sixth embodiment. The other configurations of the semiconductor device 700A are similar to the other configurations of the semiconductor device 600 in the sixth embodiment.

According to the modified example of the seventh embodiment, the second member 738A has the second recessed portion 738Ab that opens to the side (the lower side) on which the semiconductor chip 10 is located in the thickness direction Z. The first member 737A is embedded in the second recessed portion 738Ab. Therefore, the required volume of the first member 737A can be made smaller than the case in which the first member 737A and the second member 738A are bonded in the first direction X to form the first portion 737Aa and the second portion 738Aa, respectively. Thus, even when the material used to form the first member 737A is more expensive than the material used to form the second member 738A, an increase in the cost of manufacturing the first connection member 730A can be curbed. Compared to a case in which the first member 737A and the second member 738A are bonded in the first direction X, the strength of the first connection member 730A can be improved. Furthermore, a bonding area between the first member 737A and the second member 738A can be increased compared to the case in which the first member 737A and the second member 738A are bonded in the first direction X. Thus, it is possible to improve the bonding strength between the first member 737A and the second member 738A.

According to at least one of the embodiments described above, the semiconductor device has a semiconductor chip and a first conductive member electrically connected to the semiconductor chip. The semiconductor device has a second conductive member located on a first side with respect to the semiconductor chip in a predetermined direction perpendicular to a thickness direction of the semiconductor chip. The semiconductor device includes a connection member that is disposed to sandwich the semiconductor chip between the first conductive member and the connection member in the thickness direction, and electrically connects the semiconductor chip and the second conductive member. The semiconductor chip includes a first electrode that forms at least a part of a first surface of the semiconductor chip on the side on which the first conductive member is located in the thickness direction. The semiconductor chip includes a second electrode having a plurality of electrode portions. The semiconductor chip has a partition wall having a surface that forms a part of a second surface of the semiconductor chip on the side on which the connection member is located in the thickness direction. Each of the plurality of electrode portions has a surface that forms a part of the second surface. The partition wall separates two of the plurality of electrode portions from each other in a predetermined direction on the second surface. A surface of the connection member that faces the side on which the semiconductor chip is located in the thickness direction has a first portion and a second portion. The second portion overlaps the semiconductor chip when seen in the thickness direction and is electrically bonded to the plurality of electrode portions by a bonding material. The first portion is disposed on the first side of the second portion. A portion of the partition wall that forms the second surface has a lower wettability with respect to the bonding material than that of portions of the plurality of electrodes that form the second surface. The wettability of the first portion with respect to the bonding material is lower than the wettability of the second portion with respect to the bonding material. Thus, the first portion can curb the molten bonding material moving to the first side with respect to the semiconductor chip, and can curb the bonding material spreading unevenly on the second electrode of the semiconductor chip.

The bonding material in each of the above-described embodiments is not limited to the solder. The bonding material may be silver paste, or the like. The first portion may be configured in any manner as long as the first portion has the lower wettability with respect to the bonding material than the second portion. For example, the first portion and the second portion may be formed of the same material and may have different surface roughnesses such that the first portion and the second portion have different wettabilities with respect to the bonding material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip;
a first conductive member electrically connected to the semiconductor chip;
a second conductive member located on a first side with respect to the semiconductor chip in a predetermined direction perpendicular to a thickness direction of the semiconductor chip; and
a connection member disposed to sandwich the semiconductor chip between the connection member and the first conductive member in the thickness direction and configured to electrically connect the semiconductor chip and the second conductive member,
wherein the semiconductor chip includes:
a first electrode configured to form at least a part of a first surface of the semiconductor chip on a side on which the first conductive member is located in the thickness direction;
a second electrode having a plurality of electrodes; and
a partition wall having a surface that forms a part of a second surface of the semiconductor chip on a side on which the connection member is located in the thickness direction,
each of the plurality of electrodes has a surface that forms a part of the second surface,
the partition wall separates two of the plurality of electrodes from each other in the predetermined direction on the second surface,
a surface of the connection member that faces a side on which the semiconductor chip is located in the thickness direction has a first portion and a second portion,
the second portion overlaps the semiconductor chip when seen in the thickness direction and is electrically bonded to the plurality of electrodes by a bonding material,
the first portion is arranged on the first side of the second portion,
a portion of the partition wall that forms the second surface has a lower wettability with respect to the bonding material than portions of the plurality of electrodes that form the second surface, and
the first portion has a lower wettability with respect to the bonding material than a wettability of the second portion with respect to the bonding material.

2. The semiconductor device of claim 1, wherein the connection member includes a connection member main body and a first film formed on a surface of the connection member main body,
the wettability of a surface of the first film with respect to the bonding material is lower than the wettability of the surface of the connection member main body with respect to the bonding material, and
the first portion is at least a part of the surface of the first film.

3. The semiconductor device of claim 2, wherein the connection member has a second film formed on a surface of the connection member main body,
the wettability of a surface of the second film with respect to the bonding material is higher than the wettability of the surface of the connection member main body with respect to the bonding material, and
the second portion is at least a part of the surface of the second film.

4. The semiconductor device of claim 3, wherein the second film is disposed across the partition wall in the predetermined direction when seen in the thickness direction.

5. The semiconductor device of claim 1, wherein the connection member includes a connection member main body, a first film, and a second film formed on an entire surface of the connection member main body,
the first film is formed on a surface of the second film,
a wettability of a surface of the first film with respect to the bonding material is lower than a wettability of a surface of the connection member main body with respect to the bonding material,
a wettability of the surface of the second film with respect to the bonding material is higher than the wettability of the surface of the connection member main body with respect to the bonding material,
the first portion is at least a part of the surface of the first film, and
the second portion is at least a part of the surface of the second film.

6. The semiconductor device of claim 1, wherein the connection member has a connection member main body, a first film formed on an entire surface of the connection member main body, and a second film formed on a surface of the first film,
a wettability of the surface of the first film with respect to the bonding material is lower than a wettability of the surface of the connection member main body with respect to the bonding material,
a wettability of a surface of the second film with respect to the bonding material is higher than the wettability of the surface of the connection member main body with respect to the bonding material,
the first portion is at least a part of the surface of the first film, and
the second portion is at least a part of the surface of the second film.

7. The semiconductor device of claim 1, wherein the semiconductor chip has a plurality of the partition walls disposed at intervals in the predetermined direction,
the surface of the connection member that faces the side on which the semiconductor chip is located in the thickness direction has a third portion located on a second side opposite to the first side with respect to the second portion,
a wettability of the third portion with respect to the bonding material is higher than a wettability of the second portion with respect to the bonding material, and
the third portion is disposed in the predetermined direction across a partition wall that is located closest to the second side among the plurality of partition walls when seen in the thickness direction.

8. The semiconductor device of claim 1, wherein the connection member has a connection member main body that extends from a position at which it overlaps the semiconductor chip to a position at which it overlaps the second conductive member when seen in the thickness direction,
the connection member main body has a first member and a second member bonded to the first member,
a wettability of a surface of the first member with respect to the bonding material is lower than a wettability of a surface of the second member with respect to the bonding material,
the first portion is a part of the surface of the first member, and
the second portion is a part of the surface of the second member.

9. The semiconductor device of claim 8, wherein the first member is bonded to an end portion of the second member on the first side.

10. The semiconductor device of claim 9, wherein a bonding surface at which the first member and the second member are bonded to each other has a portion inclined with respect to a plane perpendicular to the predetermined direction.

11. The semiconductor device of claim 8, wherein the first member has a first recessed portion that opens to the side on which the semiconductor chip is located in the thickness direction, and
the second member is embedded in the first recessed portion.

12. The semiconductor device of claim 8, wherein the second member has a second recessed portion that opens to the side on which the semiconductor chip is located in the thickness direction, and
the first member is embedded in the second recessed portion.

13. The semiconductor device of claim 1, wherein the bonding material is solder.
